(19) United States
(12) Patent Application Publication
(10) Pub. No.: US 2006/0152150 A1
(43) Pub. Date: Jul. 13, 2006

(54) Electroluminescent display with improved light outcoupling

(76) Inventors: Herbert Boerner, Aachen (DE); Thomas Justel, Aachen (DE)

Correspondence Address: PHILIPS INTELLECTUAL PROPERTY & STANDARDS, P.O. BOX 3001, BRIARCLIFF MANOR, NY, 10510, US

(21) Appl. No.: 10/530,149

(22) PCT Filed: Sep. 23, 2003
(86) PCT No.: PCT/IB03/04116

§ 371 Date: Sep. 29, 2005

(30) Foreign Application Priority Data
Oct. 1, 2002 (EP) 02102402.1

(51) Int. Cl. H05B 33/14; H05B 33/24

(52) U.S. Cl. 313/506; 345/45; 313/503; 313/509

(57) ABSTRACT

A full color electroluminescent display is disclosed, the display including a common substrate and an array of electroluminescent devices disposed on the common substrate, wherein each of said electroluminescent devices comprises an electroluminescent layer that is sandwiched between a first and a second electrode, a color converting material that is capable of changing light emitted by the electroluminescent layer into light having a longer wavelength and a stack of 2n+1 transparent dielectric layers wherein n=0, 1, 2, 3, . . . and said transparent dielectric layers show alternating refractive indexes n. The electroluminescent display shows improved light outcoupling.

The present invention relates to an electroluminescent display comprising a common substrate and an array of electroluminescent devices disposed on the common substrate. In addition, the invention relates to an electroluminescent device.

Organic light emitting diodes (“OLEDs”) have been known for approximately two decades. All OLEDs work on the same principles. One or more lawyers of semiconducting organic material are sandwiched between two electrodes. An electric voltage is applied to the device, causing negatively charged electrons to move into the organic material(s) from the cathode. Positive charge, typically referred to as holes, moves in from the anode. The positive and negative charges meet in the center layers (i.e., the semiconducting organic material), combine, and produce a photon. The wavelength—and consequently the color—of the emitted light depend on the electronic properties of the organic material in which photons are generated. The organic material may comprise an organic electroluminescent polymer or small electroluminescent molecules. An OLED comprising an organic electroluminescent polymer is also referred to as polymer light emitting diode (polyLED or PLED). An OLED comprising electroluminescent small molecules is also referred to as small molecule organic light emitting diode (SMOLED).

An organic light-emitting device is typically a laminate formed on a substrate such as glass. An electroluminescent layer, as well as adjacent semiconductor layers, is sandwiched between a cathode and an anode. The semiconductor layers may be hole-injecting and electron-injecting layers. A typical stack is described in “Philips Journal of Research, 1998, 51, 467”.

In a typical electroluminescent display, numerous electroluminescent devices are formed on a single substrate and arranged in groups in a regular grid pattern. Addressing of the individual electroluminescent devices may be done in a passive mode or in a active mode. In a passive matrix electroluminescent display several electroluminescent devices forming a column of the grid may share a common cathode and several electroluminescent devices forming a row of the grid may share a common anode. The individual electroluminescent devices in a given group emit light when their cathodes and anodes are activated at the same time. In an active matrix electroluminescent display the individual electroluminescent devices comprise individual anode and/or cathode pads and are addressed individually.

In a full-color electroluminescent display, each electroluminescent device forms a sub-pixel of the display. Three neighboring sub-pixel emitting green, red and blue light form a pixel of the electroluminescent display. Known methods to obtain a full-color electroluminescent display include, for example, a method of color changing a blue emission. In such an electroluminescent display only a blue-emitting material is used in the electroluminescent layer of all electroluminescent devices. For a blue sub-pixel the light passes unchanged through the electroluminescent device whereas for the red or green sub-pixels the blue light is converted into red or green light, respectively, by a efficient color converting material such as a fluorescent material.

Passive matrix electroluminescent displays usually transmit the generated visible light through a transparent substrate whereas active matrix electroluminescent displays transmit light through a transparent cathode.

For efficiency reasons only metals are suitable cathode materials. To obtain a sufficient high conductivity, the metal layer needs to have a layer thickness of 10 to 30 nm that leads to low transmission of the generated visible light in an active matrix electroluminescent display.

It is an object of the present invention to provide an electroluminescent display comprising an array of electroluminescent devices with improved light outcoupling through a transparent cathode.

This object is achieved by an electroluminescent display comprising a common substrate and an array of electroluminescent devices disposed on the common substrate, wherein each of said electroluminescent devices comprise an electroluminescent layer that is sandwiched between a first and a second electrode, a color converting material that is capable of changing light emitted by the electroluminescent layer into light having a longer wavelength and a stack of 2n+1 transparent dielectric layers wherein n =0, 1, 2, 3, . . . ,

said transparent dielectric layers having a high refractive index of n>1.7 or a low refractive index of n<1.7,

said transparent dielectric layers having a high refractive index n being arranged in alternating manner with said transparent dielectric layers having a low refractive index n,

said stack of 2n+1 transparent dielectric layers being arranged adjacent to one of the electrodes and a dielectric transparent layer having a high refractive index n adjoining said electrode.

Since the dielectric layer adjoining the second electrode has a high refractive index n, reflection of visible light generated in the electroluminescent layer at the second, metallic electrode is reduced and more light passes the second electrode. With the help of the stack of transparent dielectric layers a Bragg-like optical filter is obtained. The transmission properties of the electroluminescent device can be adjusted with the help of this optical filter. Especially transmission of light or reflection of light can be adjusted in a wavelength selective manner.

The preferred transparent materials according to claim 2 and 3 show a high transmission for visible light.

A stack of transparent dielectric layers comprising the transparent dielectric materials according to claim 4 functions as an optical filter. It can be designed to show high transparency for blue light and high reflectance for red and green light and thus to enhance emission from the color converting material into forward direction.

The preferred embodiment according to claim 5 allows manufacture of large electroluminescent displays comprising large screen width.

With the preferred embodiments according to claim 6 the color converting material is placed very close but not in electrical contact with the electroluminescent layer. The proximity keeps optical cross talk small. The electroluminescent layer emits light in a hemispherical way (Frenel distribution). By placing the color converting materials close to the emitter, more light rays at the outer edge of the hemisphere are still absorbed by the color converting material and do not reach adjacent sub-pixel units.

The materials as claimed in claim 7 efficiently convert blue light into light having a longer wavelength such as red, green, orange or yellow.

The invention also relates to an electroluminescent device comprising an electroluminescent layer which is sandwiched between a first and a second electrode, a color converting material which is capable of changing light emitted by the electroluminescent layer into light having a longer wavelength and a stack of 2n+1 transparent dielectric layers wherein n=0, 1, 2, 3, . . . , said transparent dielectric layers having a high refractive index of n>1.7 or a low refractive index of n<1.7,

said transparent dielectric layers having a high refractive index n being arranged in alternating manner with said transparent dielectric layers having a low refractive index n,

said stack of 2n+1 transparent dielectric layers being arranged adjacent to one of the electrodes and a dielectric transparent layer having a high refractive index n adjoining said electrode.

The accompanying drawings, which are included to provide further understanding of the invention illustrate embodiments of the invention and together with the description serve to explain the principles of the invention.

In the drawings:

FIG. 1 illustrates a cross-sectional side view of several sub-pixels in a full color electroluminescent display according to an embodiment of the present invention.

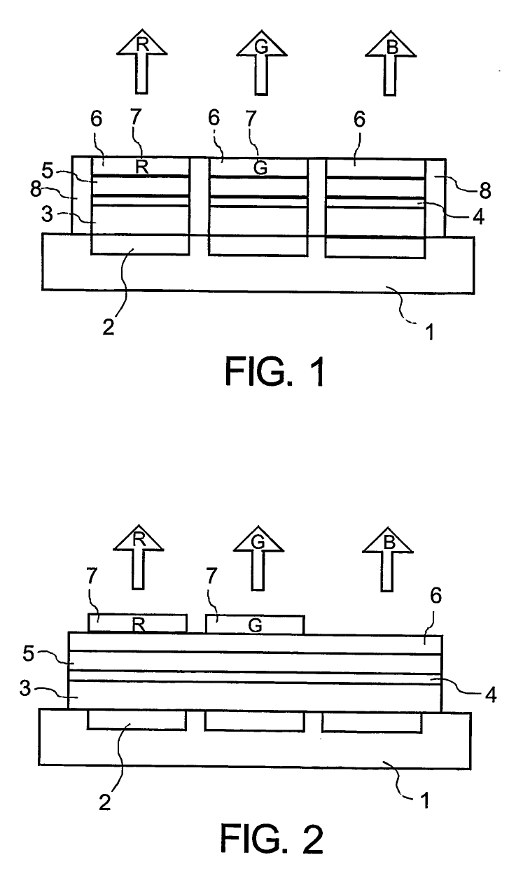

FIG. 2 illustrates a cross-sectional side view of several sub-pixels in a full color electroluminescent display according to a further embodiment of the present invention.

FIG. 1 illustrates a cross-sectional side view of several sub-pixels in a full color electroluminescent display in accordance with a preferred embodiment of the present invention. The full color electroluminescent display includes a substrate 1. The substrate 1 is preferably from an opaque material because the electroluminescent display is an upwardly emitting device. Most preferred the opaque substrate 1 comprises silicon. An active matrix addressing system having pixelated electrodes is formed in the opaque substrate 1. A pixelated electrode of the active matrix addressing system forms the first electrode 2 of an electroluminescent device. An electroluminescent layer 3 is formed on the substrate 1 and the first electrodes 2. The electroluminescent layer 3 preferably emits blue light. A second transparent electrode 4 is formed on electroluminescent layer 3. A stack 5 of 2n+1 wherein n =0, 1, 2, 3 . . . ∝ transparent dielectric layers is formed on top of the second electrode 4. The transparent dielectric layers comprise an alternating refractive index. The first group of transparent dielectric layers 9 comprises a high refractive index n>1.7 and the second group transparent dielectric layers 10 comprises a low refractive index n<1.7. The dielectric layer that is adjacent to the second electrode 4 comprises a refractive index n>1.7. The first group of transparent dielectric layers 9 may be comprised of a material selected from the group consisting of TiO₂, ZnS and SnO₂. The second group of transparent dielectric layers 10 may be comprised of a material selected from the group consisting of SiO₂, MgF₂ and alumino silicates.

A capping layer 6 is formed on top of the stack 5 of transparent dielectric layers that is transparent and impervious to moisture and/or organic solvents. Capping layer 6 may be comprised of a polymeric material such as polymethylmethacrylate, polystyrene, silicone, epoxy resin or teflon. In addition, Capping layer 6 may be comprised of a SiO₂ sol-gel-layer Color converting materials 7 capable of converting blue light into green or red light are embedded in capping layer 6 in a pixel pattern. The pixel pattern is in alignment with the pixelated pattern of the first electrode 2 in the substrate 1. In a blue-emitting sub-pixel, capping layer 6 does not contain a color converting material 7 and is only comprised of the polymeric material or SiO₂.

In order to minimize color contamination it is preferred that the electroluminescent display comprises an array of parallel walls 8 to laterally separate each sub-pixel element. The parallel walls 8 may be comprised of glass. It may be preferred that the parallel walls 8 are colored by graphite particles.

FIG. 2 shows another preferred embodiment in which the color converting materials 7 are disposed onto the capping layer 6 in a pixelated manner. Again, a blue-emitting sub-pixel does not contain color converting material 7. In this preferred embodiment, several sub-pixels share a common second electrode 4.

In another preferred embodiment a ceramic translucent layer of the color converting material 7 forms capping layer 6 in a red- emitting or green-emitting sub-pixel. A blue-emitting sub-pixel contains a glass plate as capping layer 6. In General, it is possible that the electroluminescent display does not only comprise red, green and blue sub-pixel but also yellow or orange sub-pixels.

The color converting materials 7 show a strong absorption between 350 and 500 nm and an emission between 520 and 550 nm for green or an emission between 600 and 650 nm for red. In addition, the color converting materials 7 have high (>90%) fluorescence quantum efficiencies. Suitable color converting materials 7 may comprise inorganic phosphors. Inorganic phosphors are especially suitable for environments with high optical flux and/or higher temperatures. Suitable color converter materials 7 may also comprise organic fluorescent materials. Organic fluorescent materials are especially suitable for environments with less optical flux and ambient temperatures. In addition, quantum dots like CdS, CdSe or InP may be used. The emission spectra of the quantum dots can be controlled and adjusted by their size.

Table 1 lists suitable color converting materials 7 for down-conversion of blue light.

TABLE 1
Suitable color converting materials
7 for down-conversion of blue light

| Color converting material | Emission color | Emission wavelength [nm] |
|---|---|---|
| (Ba,Sr)₂SiO₄:Eu | green | 525 |
| SrGa₂S₄:Eu | green | 535 |
| CaS:Ce | green | 520 |
| Ba₂ZnS₃:Ce,K | green | 525 |
| Lumogen yellow ED206 | yellow | 555 |
| (Sr, Ca)₂SiO₄:Eu | yellow | 575 |
| Y₃Al₅O₁₂:Ce | yellow | 570 |
| (Y, Gd)₃(Al, Ga)₅O₁₂:Ce | yellow | 575 |
| Lumogen F orange 240 | orange | 545, 575 |
| SrGa₂S₄:Pb | orange | 595 |
| Sr₂Si₅N₈:Eu | red | 610 |
| SrS:Eu | red | 610 |
| Lumogen F red 300 | red | 615 |
| Ca₂Si₅N₈:Eu | red | 605 |
| Ba₂Si₅N₈:Eu | red | 640 |
| CaSiN₂:Eu | red | 620 |
| CaS:Eu | red | 650 |

Ink jet printing can do application of the color converting materials 7 onto capping layer 6 in an electroluminescent display according to FIG. 2. This method be specially suitable for organic fluorescent materials and inorganic phosphors if the grain size of the latter is small enough. For some inorganic phosphors also vapor deposition processes are applicable. In general, printing with micro-stencils is an option for all materials.

In case the color converting materials 7 are embedded into capping layer 6 a monomeric precursor of the material used in capping layer 6 is mixed with the color converting material 7. After application the obtained mixture is polymerized by thermal or photochemical initiation.

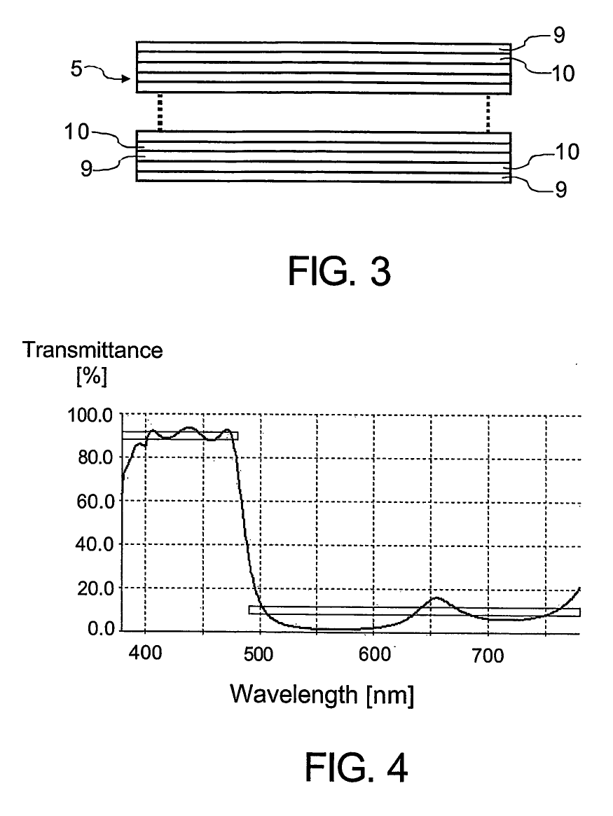

FIG. 3 shows an enlarged view of the stack 5 of transparent layers. As mentioned above the layers of the first group of transparent dielectric layers 9 alternate with layers of the second group of transparent dielectric layers 10.

FIG. 4 shows the transmission curve of a 15 nm silver layer that is covered by a stack 5 of nineteen layers that in alternating manner comprise ZnS and MgF₂. The stack 5 of transparent dielectric layers shows a high transparency in the blue region of the visible spectra and high reflectance for the green and the red regions of the visible light. This measure enhances light emission from the color converting material-containing layer into the forward direction. With the help of the stack 5 of transparent dielectric layers the red and the green light is reflected immediately so that it gets not further into the device. On the other hand the stimulating blue light passes the stack 5 of transparent dielectric layers almost without losses.

1. An electroluminescent display comprising a common substrate and an array of electroluminescent devices disposed on the common substrate, wherein each of said electroluminescent devices comprise an electroluminescent layer which is sandwiched between a first and a second electrode, a color converting material which is capable of changing light emitted by the electroluminescent layer into light having a longer wavelength and a stack of 2n+1 transparent dielectric layers wherein n =0, 1, 2, 3, . . . ,
said transparent dielectric layers having a high refractive index of n>1.7 or a low refractive index of n<1.7,
said transparent dielectric layers having a high refractive index n being arranged in alternating manner with said transparent dielectric layers having a low refractive index n,
said stack of 2n+1 transparent dielectric layers being arranged adjacent to one of the electrodes and a dielectric transparent layer having a high refractive index n adjoining said electrode.

2. An electroluminescent display as claimed in claim 1, wherein said transparent dielectric layers having a refractive index n>1.7 is selected from the group consisting of TiO₂, ZnS and SnO₂.

3. An electroluminescent display as claimed in claim 1, wherein said transparent dielectric layers having a refractive index n<1.7 is selected from the group consisting of SiO₂, MgF₂ and alumino silicates.

4. An electroluminescent display as claimed in claim 1, wherein said transparent dielectric layers having a high refractive index n is ZnS and said transparent dielectric layers having a low refractive index n is MgF₂.

5. An electroluminescent display as claimed in claim 1, wherein said electroluminescent device is an active matrix device having a pixelated first electrode.

6. An electroluminescent display as claimed in claim 1, wherein a capping layer is placed adjacent to the second electrode and wherein the color converter material is embedded in or placed on top of the capping layer.

7. An electroluminescent display as claimed in one of the claims 1 to 6, wherein the color converting material is selected from the group consisting of (Ba,Sr)₂SiO₄:Eu, SrGa₂S₄:Eu, CaS:Ce, Ba₂ZnS₃:Ce,K, Lumogen yellow ED206, (Sr;Ca)₂SiO₄:Eu, (Y,Gd)₃(Al,Ga)₅O₁₂:Ce, Y₃Al₅O₁₂:Ce, Lumogen F orange 240, SrGa₂S₄:Pb, Sr₂Si₅N₈:Eu, SrS:Eu, Lumogen F red 300, Ba₂Si₅N₈:Eu, Ca₂Si₅N₈:Eu CaSiN₂:Eu and CaS:Eu.

8. An electroluminescent device comprising an electroluminescent layer which is sandwiched between a first and a second electrode, a color converting material which is capable of changing light emitted by the electroluminescent layer into light having a longer wavelength and a stack of 2n+1 transparent dielectric layers wherein n =0, 1, 2, 3, . . . ,
said transparent dielectric layers having a high refractive index of n>1.7 or a low refractive index of n<1.7,
said transparent dielectric layers having a high refractive index n being arranged in alternating manner with said transparent dielectric layers having a low refractive index n,
said stack of 2n+1 transparent dielectric layers being arranged adjacent to one of the electrodes and a dielectric transparent layer having a high refractive index n adjoining said electrode.
